(19) United States
(12) Patent Application Publication
(10) Pub. No.: US 2008/0270828 A1
(43) Pub. Date: Oct. 30, 2008

(54) Memory Redundancy Method and Apparatus

(76) Inventor: Hermann Wienchol, Raleigh, NC (US)

Correspondence Address: COATS & BENNETT/QIMONDA, 1400 CRESCENT GREEN, SUITE 300, CARY, NC, 27518, US

(21) Appl. No.: 11/741,337

(22) Filed: Apr. 27, 2007

(51) Int. Cl. G01R 31/28

(52) U.S. Cl. 714/12

(57) ABSTRACT

Redundancy is provided in a memory device having a configurable data bus organization by associating a redundant memory location with a defective memory location and configuring a size of the redundant memory location based on the current data bus organization of the memory device.

### BACKGROUND OF THE INVENTION

A single failing memory cell amongst millions in a memory device causes failure. Memory devices are tested at several levels of fabrication and assembly to determine whether defective memory cells are present. Identified defects are repaired using redundancy included within a memory device, thus improving manufacturing yields. Redundancy is implemented by replacing a defective memory location with a redundant memory element during normal operation when the defective memory location is addressed.

A fuse array such as a metal or electronic fuse array included in a memory device conventionally stores addresses identifying defective memory locations. The fuse array is programmed during testing responsive to detecting one or more defective memory locations within a memory array. During functional operation, latches capture the state of the fuse array. Latched address information is compared against addresses provided to the memory device during normal operation. In the event of a match, the corresponding defective memory location is replaced with a redundant word line. Particularly, data read from or written to a defective memory location is redirected to a redundant word line, thus maintaining data integrity within the memory device. However, redundant word lines conventionally have a width matching the widest data bus organization available for a particular memory device.

As such, redundant word lines are addressed based on the widest data bus configuration available to a memory device even though the data bus may be organized in one of various predefined widths such as 4 bits, 8 bits, 16 bits, etc. For example, a memory device configurable in 4, 8 and 16 bit data bus widths (also referred to as ×4, ×8 and ×16) conventionally includes a redundant memory array having word lines addressable in 16 bit segments. While no inefficiency arises when the data bus width is configured at 16 bits, only half of the redundant memory array is utilized when the data bus is 8 bits wide. That is, only half of each 16-bit redundant word line is used to store 8-bit redundancy data because the redundant memory array is addressable in 16 bit segments. The other half of each redundant word line goes unused in conventional memory devices. Redundancy utilization drops to 25% when the device is configured with a 4-bit data bus (only a quarter of each 16-bit redundant word line is used to store 4-bit redundancy data).

### SUMMARY OF THE INVENTION

According to the methods and apparatus taught herein, redundancy is provided in a memory device having a configurable data bus organization by associating a redundant memory location with a defective memory location and configuring a size of the redundant memory location based on the current data bus organization of the memory device.

Of course, the present invention is not limited to the above features and advantages. Those skilled in the art will recognize additional features and advantages upon reading the following detailed description, and upon viewing the accompanying drawings.

### BRIEF DESCRIPTION OF THE DRAWINGS

FIG. 1 is a block diagram of an embodiment of a memory device including redundancy control logic.

FIG. 2 is a logic flow diagram of an embodiment of program logic for implementing redundancy in the memory device of FIG. 1.

FIG. 3 is a block diagram of one embodiment of address mapping circuitry included in or associated with the redundancy control logic of FIG. 1.

FIG. 4 is a block diagram of an embodiment of a redundant memory circuit included in the memory device of FIG. 1.

FIG. 5 is a diagram of an embodiment of an address mapping function implemented by the address mapping circuitry of FIG. 3.

FIG. 6 is a block diagram of another embodiment of address mapping circuitry included in or associated with the redundancy control logic of FIG. 1.

FIG. 7 is a diagram of an embodiment of an address mapping function implemented by the address mapping circuitry of FIG. 6.

### DETAILED DESCRIPTION OF THE INVENTION

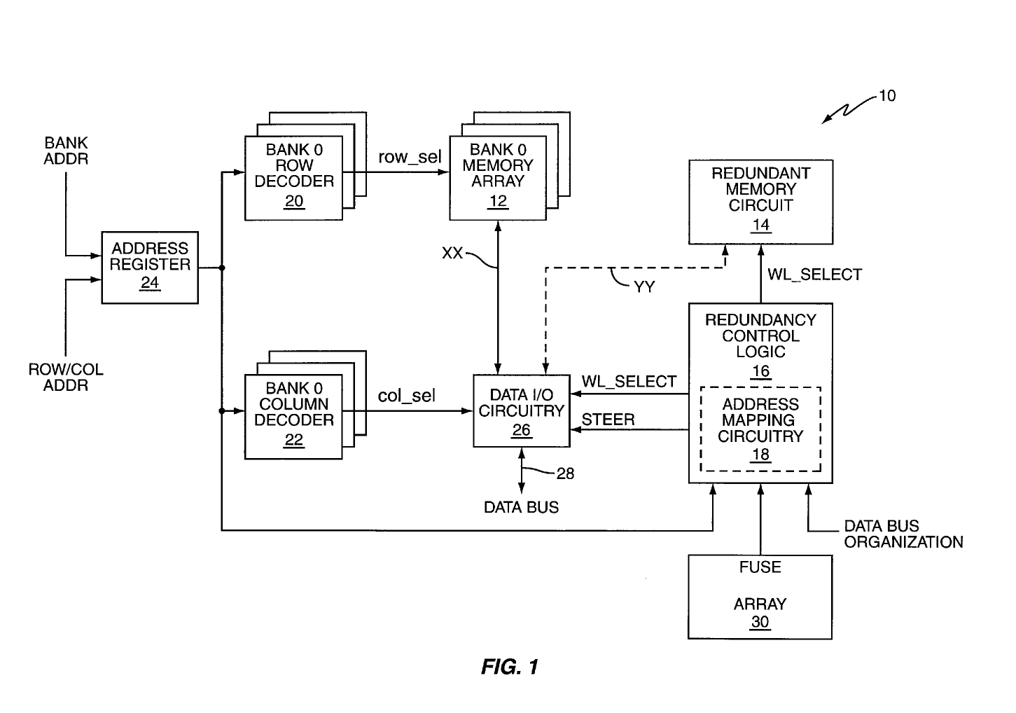

FIG. 1 illustrates an embodiment of a memory device 10 including a memory array 12 arranged as one or more separately addressable banks of memory cells. The memory array 12 may comprise any kind of volatile or non-volatile memory such as Dynamic Random Access Memory (DRAM), embedded-DRAM, Static Random Access Memory (SRAM), Magneto-resistive Random Access Memory (MRAM), FLASH, etc. The memory device 10 also includes a redundant memory circuit 14 for replacing defective memory locations in the memory array 12. The redundant memory circuit 14 may also comprise any kind of volatile or non-volatile memory such as the kinds previously mentioned.

Control logic 16 included in the memory device 10 manages access to the redundant memory circuit 14. The redundancy control logic 16 determines when redundancy is implemented and how it is organized. Address mapping circuitry 18 included in or associated with the redundancy control logic 16 segments the redundant memory circuit 14 into separately addressable locations each having a size corresponding to the current data bus organization of the memory device 10. This way, the redundant memory circuit 14 is addressable in the same size segments as the memory array 12, thus maximizing redundancy utilization for all data bus organizations.

In more detail, a particular location within the memory array 12 is accessible by selecting the corresponding row, column and bank (if multiple banks are provided as shown in FIG. 1). Row and column address decoders 20, 22 select a desired memory array location based on bank (BANK ADDR), row (ROW ADDR) and column (COL ADDR) address information, respectively, received by the memory device 10 and stored in an address register 24. The width of the addressed memory location corresponds to the current data bus organization of the memory device 10, e.g., 4 bits, 8 bits, 16 bits, etc. The current data bus organization may be set by activating certain pins (not shown) external to the memory device 10 or by otherwise indicating data bus width to the memory device 10. Data Input/Output (I/O) circuitry 26 controls the flow of data between the memory array 12 and the memory device data bus 28 and may include masking logic, gating logic, write drivers, sense amplifiers, latches, etc.

Data flows between the memory array 12 and the data I/O circuitry 26 as shown by the solid line ‘XX’ in FIG. 1 when the addressed memory location is not recognized as defective. Otherwise, data flows between the redundant memory circuit 14 and the data I/O circuitry 26 as shown by the dashed line ‘YY’ in FIG. 1. The redundancy control logic 16 provides a signal (STEER) to the data I/O circuitry 26 identifying which data path should be enabled. The control logic 16 determines which data path should be followed based on whether the current memory address corresponds to a known defective location in the memory array 12. The control logic 16 identifies defective memory locations by comparing the address associated with a current memory operation to address information stored in a fuse array 30 included in the memory device 10. The fuse array 30 may comprise metal or electronic fuse (or anti-fuse) elements and latch circuitry for capturing the state of the fuse elements. The fuse array 30 stores address information identifying defective locations within the memory array 12, e.g., bank, row and column addresses.

If the memory address associated with a current memory operation does not match the address information stored by the fuse array 30, the redundancy control logic 16 instructs the data I/O circuitry 26 to couple the memory array 12 to the data bus 28. Data is then read from or written to the addressed location within the memory array 12. If, however, the current memory address matches a fuse array entry, redundancy is utilized. To this end, the control logic 16 instructs the data I/O circuitry 26 to couple the data bus 28 to the redundant memory circuit 14. The memory access initially directed to the defective memory location is then redirected to a selected location in the redundant memory circuit 14, the selected location configured to have a size based on the current data bus organization of the memory device 10. While data may also flow to and from the memory array 12 when redundancy is utilized, the data I/O circuitry 26 ensures that data retrieved from the redundant memory circuit 14 supersedes other data on the data bus 28.

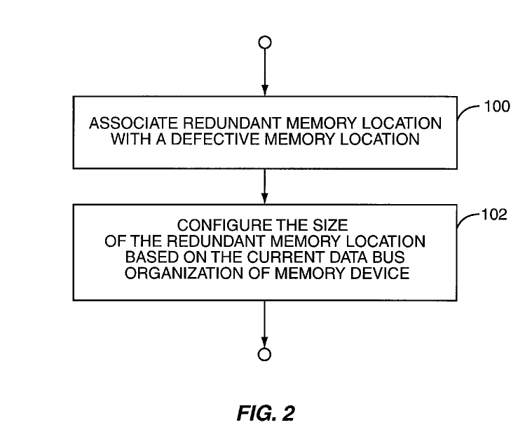

The redundancy control logic 16 redirects memory accesses to the redundant memory circuit 14 by associating locations in the redundant memory circuit 14 with defective locations in the memory array 12, e.g., as illustrated by Step 100 of FIG. 2. In one embodiment, the address mapping circuitry 18 maps the address identifying a defective memory location to an address identifying a particular location in the redundant memory circuit 14. Further, each addressable redundant memory location is configured to have a size based on the current data bus organization of the memory device 10, e.g., as illustrated by Step 102 of FIG. 2. In one embodiment, the address space used by the address mapping circuitry 18 is a function of the current data bus organization of the memory device 10. That is, more address bits are used to select more granular locations in the redundant memory circuit 14 when the data bus 28 is narrow (e.g., 4 or 8 bits). Conversely, less address bits are used when the data bus 28 is wide (e.g., 16 or 32 bits). This way, the redundancy control logic 16 segments the redundant memory circuit 14 into addressable locations having a size corresponding to the current data bus width, thus maximizing utilization of the redundant memory circuit 14.

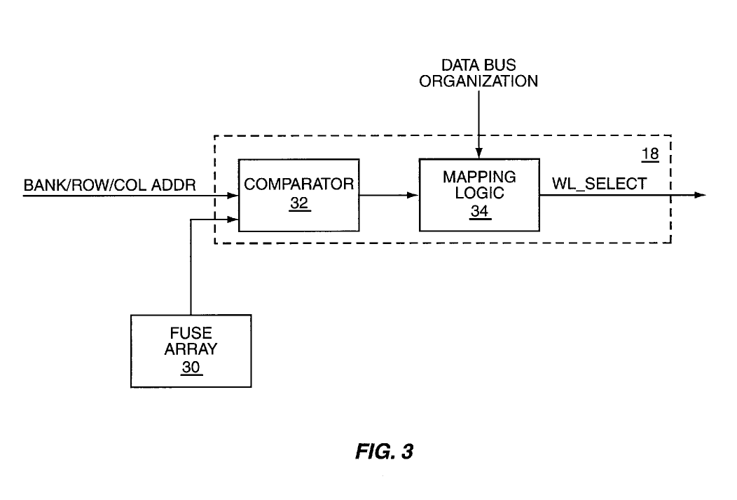

FIG. 3 illustrates one embodiment of the address mapping circuitry 18 included in or associated with the redundancy control logic 16. During operation, a comparator 32 determines whether the bank, row and column address associated with the current memory operation matches any of the fuse array entries. A match indicates the current memory operation is directed to a known defective location in the memory array 12. In the event of a match, mapping logic 34 such as a state machine, lookup table or other logic selects a redundant memory circuit address (WL_SELECT) based on the current data bus organization. The selected address identifies a location in the redundant memory circuit 14 having a length corresponding to the current width of the memory device data bus 28. For example, if the data bus 28 is currently four bits wide, the redundant memory address identifies a 4-bit location in the redundant memory circuit 14. If the data bus 28 is eight bits wide, the redundant memory address identifies an 8-bit location in the redundant memory circuit 14 and so on. The address is provided to the redundant memory circuit 14 for selecting the identified redundant memory location and to the data I/O circuitry 26 for steering the current memory access to the selected redundant memory location.

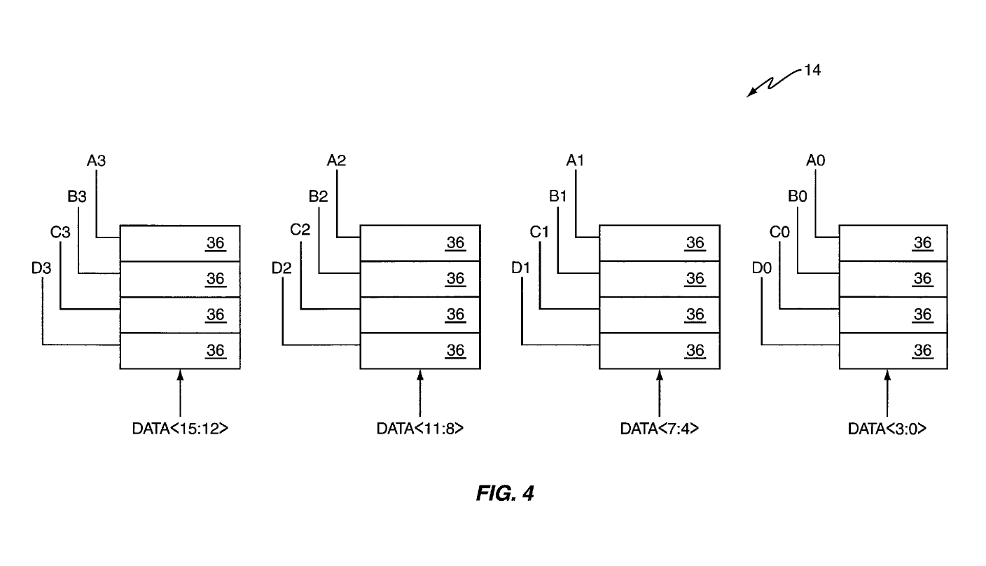

FIG. 4 illustrates an embodiment of the redundant memory circuit 14. Preferably, the smallest addressable segment 36 included in the redundant memory circuit 14 has a size corresponding to the narrowest data bus organization available to the memory device 10. This way, each segment 36 may be individually associated with a failing memory location when the data bus 28 is organized in the narrowest configuration, e.g., four bits wide. However, when the data bus 28 is organized in wider configurations, two or more segments 36 may be grouped together to form a single addressable location for accommodating larger chunks of redundancy data. As such, the redundant memory circuit 14 is dividable into addressable locations having a size corresponding to the current data bus organization of the memory device 10.

In the present embodiment, the redundant memory circuit 14 has the capacity to provide four 16-bit redundant memory locations (A0/A1/A2/A3, . . . , D0/D1/D2/D3), eight 8-bit redundant memory locations (A0/A1, A2/A3, . . . , D0/D1, D2/D3) or sixteen 4-bit redundant memory locations (A0, A1, . . . , D2, D3). When the data bus 28 is four bits wide, the address space used by the redundancy control logic 16 includes four bits for uniquely selecting individual ones of the sixteen 4-bit redundant memory locations. For example, redundant memory location ‘B0’ may be selected by activating the 4-bit address identifying ‘B0’. The address activates the word lines associated with ‘B0’. The bit lines associated with ‘B0’ are then coupled to the four least-significant bits (<3:0>) of the data bus 28 (DATA<15:0>), thus enabling the flow of data to or from ‘B0’.

Likewise, when the data bus 28 is eight bits wide, the address space used by the redundancy control logic 16 includes three bits for uniquely selecting respective ones of the 8-bit redundant memory locations. For example, 8-bit redundant memory location ‘C2/C3’ is selected by activating the corresponding 3-bit address. The address activates the word lines associated with ‘C2/C3’. The bit lines associated with ‘C2/C3’ are then coupled to the eight most-significant bits (<15:8>) of the data bus 28 (DATA<15:0>), thus enabling the flow of data to or from ‘C2/C3’. Similarly, two addressing bits are used to uniquely select respective ones of the 16-bit redundant memory locations when the data bus 28 is sixteen bits wide. Of course, those skilled in the art will readily recognize that the redundant memory circuit 14 may be of any organization and capacity, and thus, the present embodiment should be considered non-limiting. Accordingly, the redundant memory circuit 14 may be segmented into uniquely addressable locations having a size corresponding to the current data bus width of the memory device 10 regardless of the particular organization and capacity of the redundant memory circuit 14.

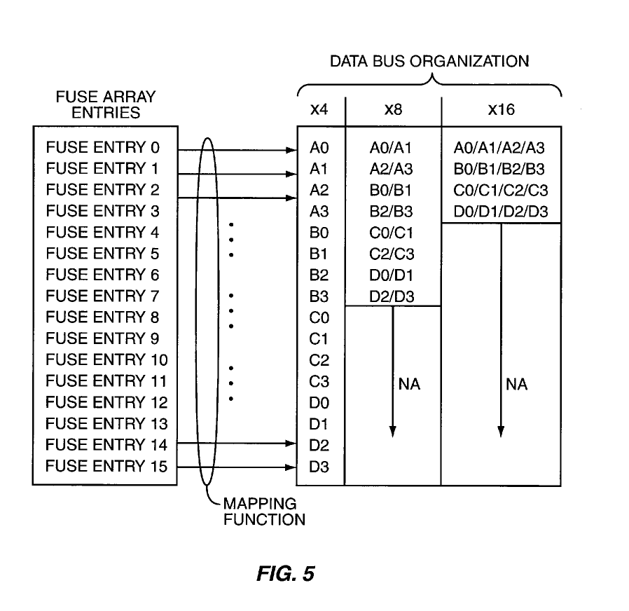

FIG. 5 illustrates one embodiment of a mapping function implemented by the mapping logic 34 of FIG. 3 for segmenting the redundant memory circuit 14 based on the current data bus organization of the memory device 10. The mapping function illustrated in FIG. 5 is explained next based on the redundant memory circuit embodiment of FIG. 4 for ease of explanation only. However, those skilled in the art will readily recognize the mapping function applies to any redundant memory circuit capacity and organization. With this in mind, the mapping logic 34 associates fuse array entries with locations in the redundant memory circuit 14. When the contents of a fuse entry match an address associated with a current memory operation, the mapping logic 34 provides a redundant memory circuit address based on the predefined associations maintained by the mapping logic 34. The address provided by the mapping logic 34 identifies a location in the redundant memory circuit 14 for storing data initially directed to a failing location in the memory array 12.

The size of the redundant memory location identified by the address is based on the current data bus organization of the memory device 10. For example, if the fuse array 30 comprises sixteen entries, all sixteen entries (fuse entry 0, fuse entry 1, . . . , fuse entry 15) are mapped to a corresponding 4-bit location (A0, A1, . . . , D3) in the redundant memory circuit 14 of FIG. 4 when the data bus 28 is four bits wide. Likewise, half of the fuse entries (fuse entry 0, fuse entry 1, . . . , fuse entry 7) are mapped to respective 8-bit locations (A0/A1, A2/A3, . . . , D2/D3) when the data bus 28 is eight bits wide. When the data bus 28 is sixteen bits wide, a quarter of the fuse array entries (fuse entry 0, fuse entry 1, . . . , fuse entry 3) are mapped to respective 16-bit locations (A0/A1/A2/A3, B0/B1/B2/B3, . . . , D0/D1/D2/D3) in the redundant memory circuit 14. The mapping logic 34 may be implemented as a lookup table when the mapping function is based on entry position in the fuse array 30, thus reducing complexity of the address mapping circuitry 18.

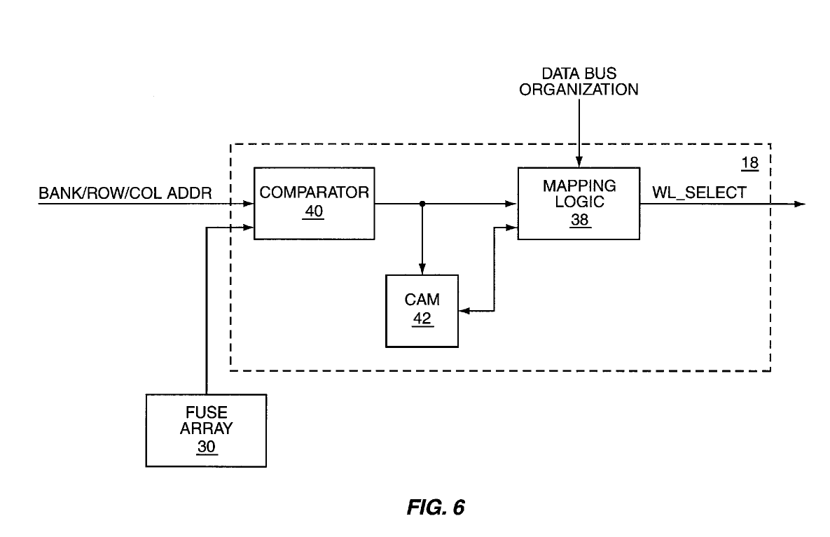

FIG. 6 illustrates another embodiment of the address mapping circuitry 18. According to this embodiment, mapping logic 38 implements a mapping function based on the order in which failing memory addresses are identified by comparator 40, not predefined fuse array entry positioning. This way, redundant memory locations are not always associated with the same failing memory addresses, thus reducing the likelihood of reliability wearout within the redundant memory circuit 14. For example, if four failing memory addresses are stored in the fuse array 30, the same redundant memory locations are not always associated with the four addresses. Instead, locations in the redundant memory circuit 14 are allocated based on the order in which the four addresses are recognized by the comparator 40, not the predefined order in which they are stored in the fuse array 30. This may differ from application to application, thus partially randomizing the allocation of redundant memory locations.

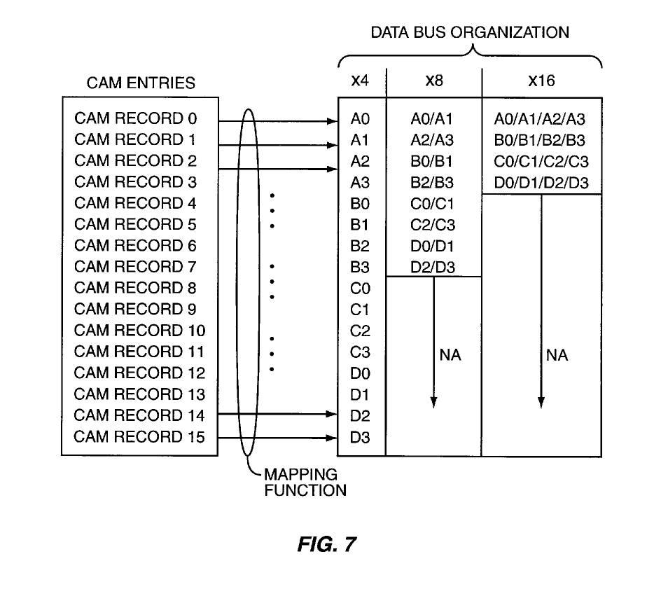

When a failing memory address is recognized by the comparator 40, a Content Addressable Memory (CAM) 42 stores information indicating a match occurred, e.g., the matching address. The mapping logic 38 accesses the CAM 42 and allocates redundant memory locations based on the order in which records are maintained in the CAM 42 and the current data bus organization of the memory device 10, e.g., as shown in FIG. 7. This way, when the comparator 40 detects a matching address, the corresponding CAM record is identified. The mapping logic 38 provides a redundant memory circuit address (WL_SELECT) associated with the identified CAM record. The address identifies a location in the redundant memory circuit 14 having a length corresponding to the current data bus organization of the memory device 10. The mapping embodiment shown in FIG. 7 differs from the one illustrated in FIG. 5 in that redundant memory locations are allocated based on CAM record positioning and not fuse array entry positioning. However, in both embodiments, the size of addressable redundant memory locations is based on the current data bus organization of the memory device 10 as previously described.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of providing redundancy in a memory device having a configurable data bus organization, comprising:
associating a redundant memory location with a defective memory location; and
configuring a size of the redundant memory location based on the current data bus organization of the memory device.

2. The method of claim 1, wherein configuring the size of the redundant memory location comprises selecting a redundant memory address configured to identify a location in a redundant memory circuit having a length corresponding to the current data bus organization of the memory device.

3. The method of claim 2, wherein selecting the redundant memory address comprises mapping a memory address identifying the defective memory location to the redundant memory address based on the current data bus organization of the memory device.

4. The method of claim 2, further comprising accessing the redundant memory location based on the redundant memory address when the defective memory location is addressed.

5. The method of claim 1, further comprising reconfiguring the size of the redundant memory location responsive to a change in the data bus organization of the memory device.

6. A memory device having a configurable data bus organization, the memory device comprising circuitry configured to associate a redundant memory location with a defective memory location and configure a size of the redundant memory location based on the current data bus organization of the memory device.

7. The memory device of claim 6, wherein the circuitry is configured to select a redundant memory address configured to identify a location in a redundant memory circuit included in the memory device having a length corresponding to the current data bus organization of the memory device.

8. The memory device of claim 7, wherein the circuitry is configured to map a memory address identifying the defective memory location to the redundant memory address based on the current data bus organization of the memory device.

9. The memory device of claim 7, wherein the circuitry is further configured to enable access to the redundant memory location based on the redundant memory address when the defective memory location is addressed.

10. The memory device of claim 6, wherein the circuitry is further configured to reconfigure the size of the redundant memory location responsive to a change in the data bus organization of the memory device.

11. A memory device having a configurable data bus organization, the memory device comprising:
circuitry configured to associate a redundant memory location with a defective memory location; and
means for configuring a size of the redundant memory location based on the current data bus organization of the memory device.

12. A method of providing redundancy in a memory device having a configurable data bus organization, comprising:
segmenting a redundant memory circuit associated with the memory device into a plurality of locations based on the current data bus organization of the memory device; and
redirecting a memory access directed to a defective memory location to one of the redundant memory circuit locations.

13. The method of claim 12, wherein segmenting the redundant memory circuit comprises selecting an address space configured to activate the redundant memory circuit in respective segments having a size corresponding to the current data bus organization of the memory device.

14. The method of claim 13, wherein redirecting the memory access comprises:
selecting an address from the address space based on an address associated with the memory access; and
accessing the redundant memory circuit location identified by the selected address.

15. The method of claim 14, wherein selecting the address from the address space comprises mapping the address associated with the memory access to the address space.

16. The method of claim 12, further comprising re-segmenting the redundant memory circuit responsive to a change in the data bus organization of the memory device.

17. A memory device having a configurable data bus organization, comprising:
a memory array;
a redundant memory circuit; and
circuitry configured to segment the redundant memory circuit into a plurality of locations based on the current data bus organization of the memory device and redirect a memory access directed to a defective memory array location to one of the redundant memory circuit locations.

18. The memory device of claim 17, wherein the circuitry is configured to select an address space configured to activate the redundant memory circuit in respective segments having a size corresponding to the current data bus organization of the memory device.

19. The memory device of claim 18, wherein the circuitry is configured to select an address from the address space based on an address associated with the memory access and enable access to the redundant memory circuit location identified by the selected address.

20. The memory device of claim 19, wherein the circuitry is configured to map the address associated with the memory access to the address space.

21. The memory device of claim 17, wherein the circuitry is further configured to re-segment the redundant memory circuit responsive to a change in the data bus organization of the memory device.
